(19) United States
(12) Patent Application Publication
(10) Pub. No.: US 2011/0156810 A1
(43) Pub. Date: Jun. 30, 2011

(54) INTEGRATED DMOS AND SCHOTTKY

(75) Inventors: Dev Alok Girdhar, Indialantic, FL (US); Michael David Church, Sebastian, FL (US)

(73) Assignee: Intersil Americas Inc.

(21) Appl. No.: 12/944,836

(22) Filed: Nov. 12, 2010

Related U.S. Application Data
(60) Provisional application No. 61/291,124, filed on Dec. 30, 2009.

(51) Int. Cl. G11C 7/16; H01L 29/78; H01L 21/336

(52) U.S. Cl. 327/566; 257/384; 438/237; 257/E29.271; 257/E21.45

(57) ABSTRACT

Embodiments relate generally to voltage converter structures including a diffused metal oxide semiconductor (DMOS) field effect transistors (FET). Embodiments include the combination of DMOS devices (e.g., FETs with isolated bodies from the substrate) with Schottky diodes on a single semiconductor die. The Schottky diode can be integrated into a cell of a DMOS device by forming an N-type area in the P-body region of the DMOS device.

### CROSS-REFERENCE TO RELATED APPLICATION

This application claims benefit of provisional U.S. Patent Application Ser. No. 61/291,124 filed Dec. 30, 2009, which is incorporated herein by reference in its entirety.

### DESCRIPTION OF THE EMBODIMENTS

It should be noted that some details of the FIGS. have been simplified and are drawn to facilitate understanding of the inventive embodiments rather than to maintain strict structural accuracy, detail, and scale. It should also be noted that not all manufacturing steps are illustrated, as the general methods of semiconductor manufacturing are well known.

Reference will now be made in detail to the present embodiments (exemplary embodiments) of the present teachings, examples of which are illustrated in the accompanying drawings. Wherever possible, the same reference numbers will be used throughout the drawings to refer to the same or like parts.

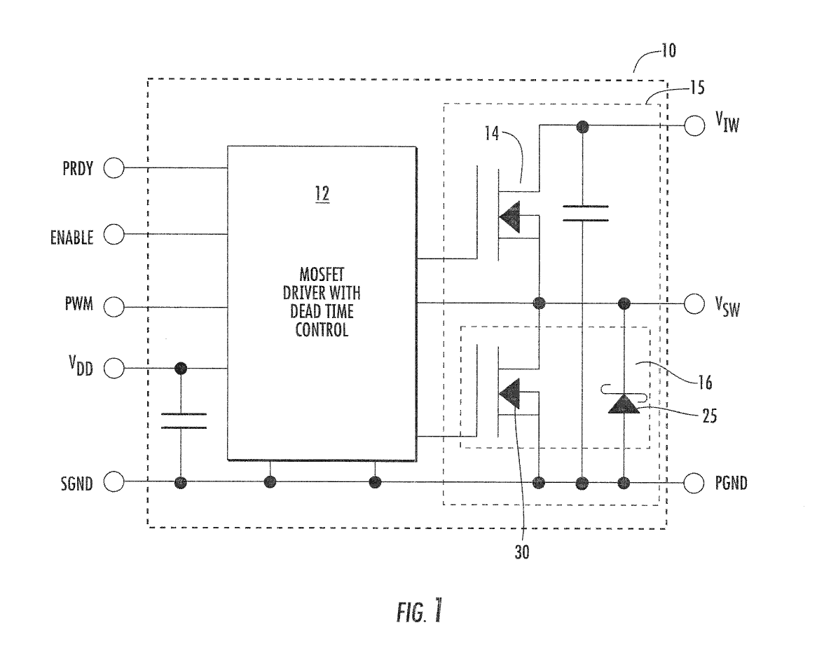

FIG. 1 is a block diagram of an embodiment of a voltage converter device including low side and high side output power devices on a single die;

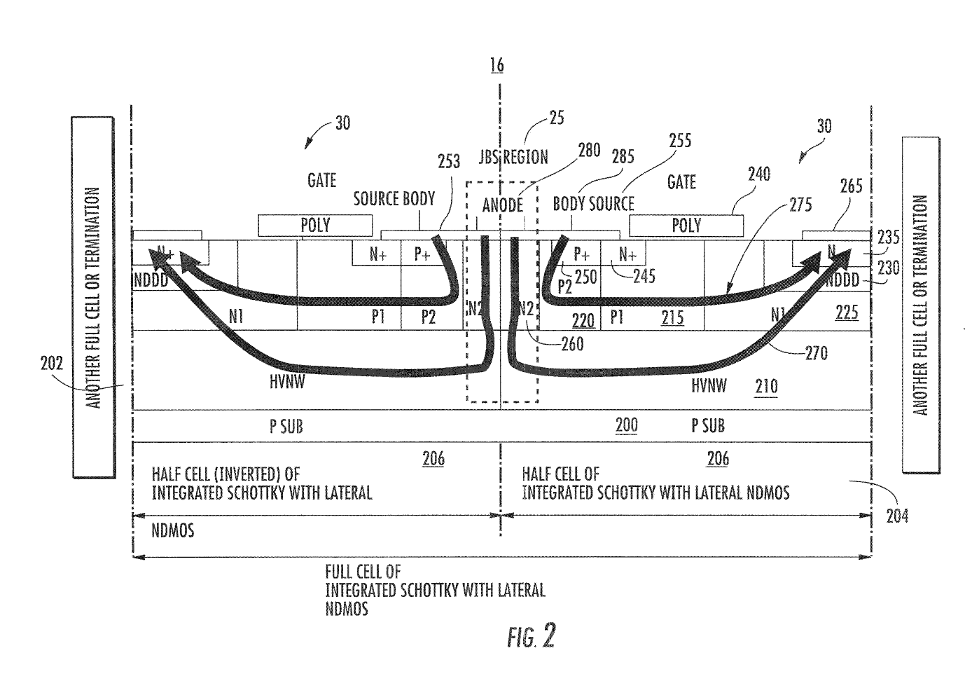

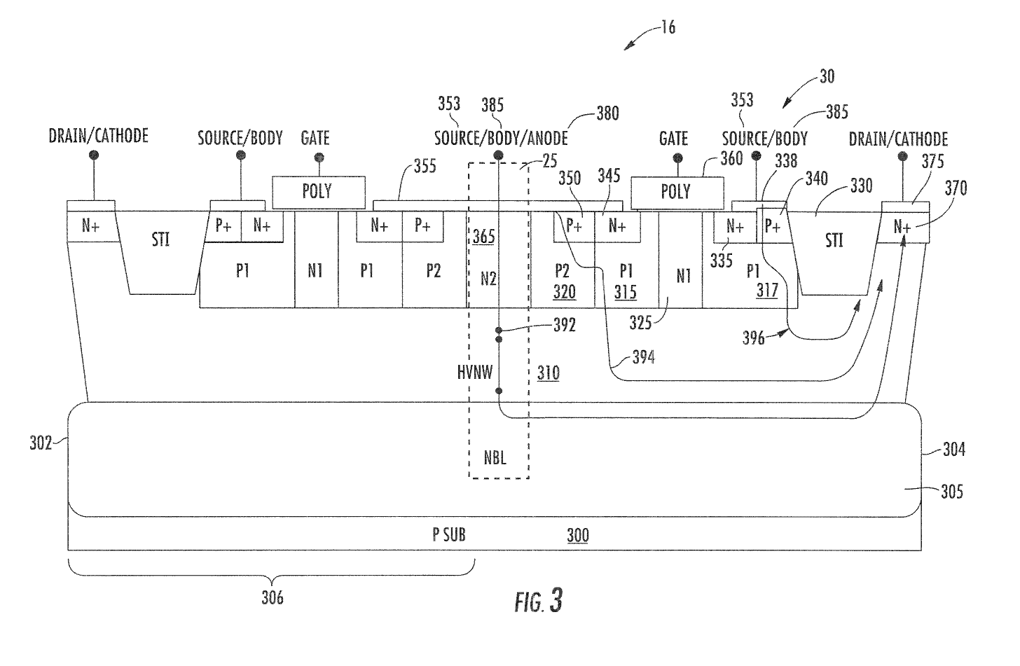

FIGS. 2-3 are cross sections depicting embodiments in accordance with the present teachings;

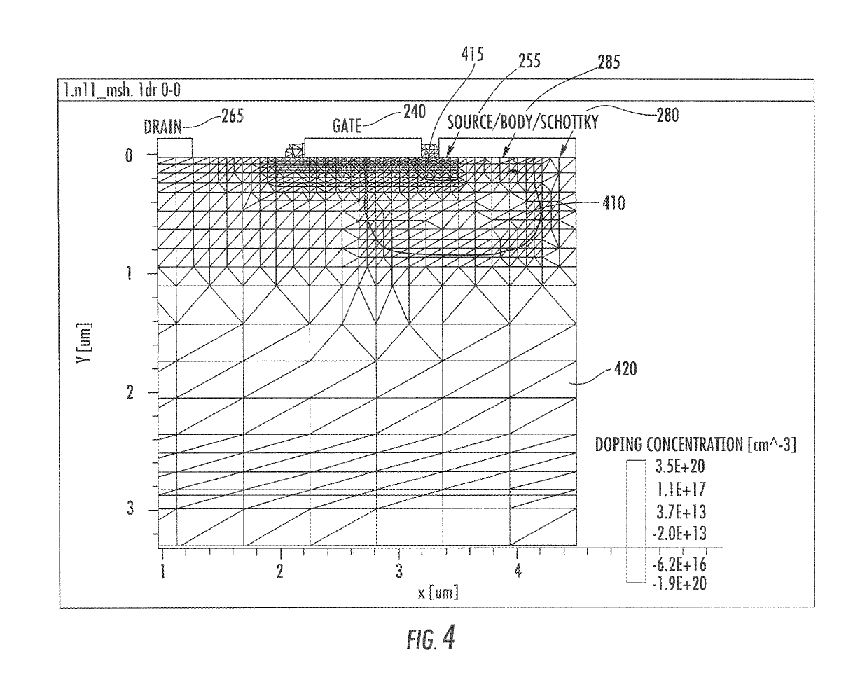

FIG. 4 is a graphical representation of simulated doping concentrations in accordance with one or more embodiments of the present teachings;

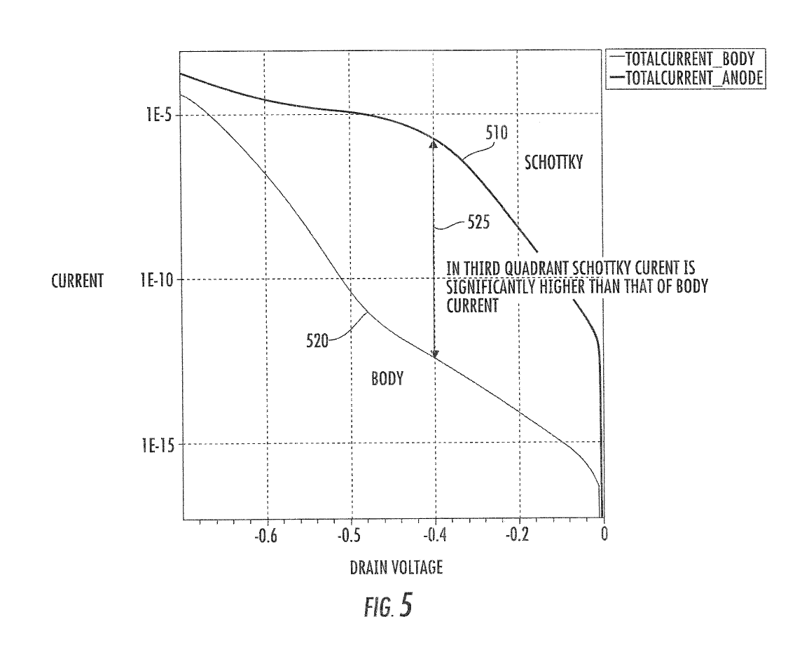

FIG. 5 is a current-drain voltage graph in accordance with one or more embodiments of the present teachings; and

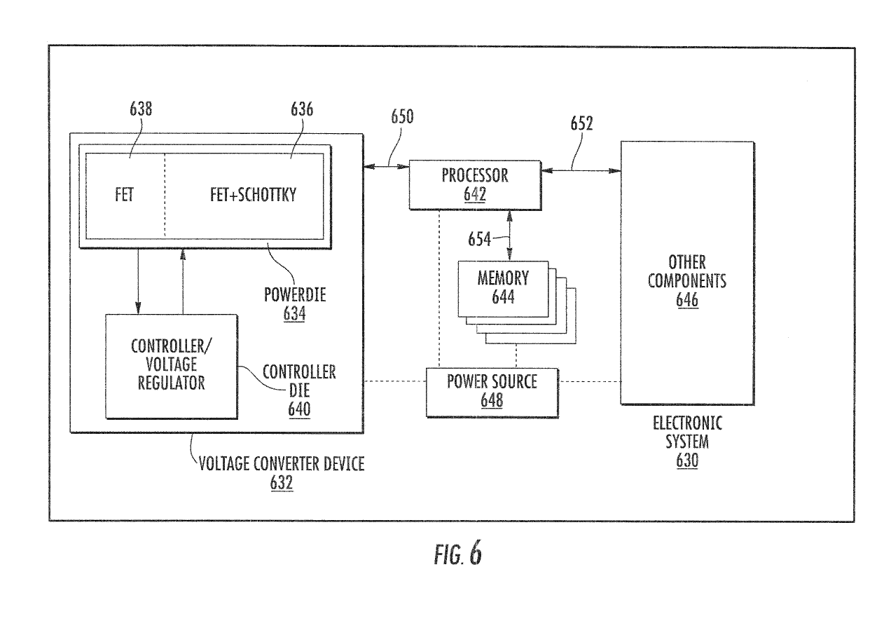

FIG. 6 is a block diagram of an electronic system which can be formed according to embodiments of the present teachings.

Embodiments relate generally to voltage converter structures including a diffused metal oxide semiconductor (DMOS) field effect transistors (FET). Embodiments can include the combination of, for example, lateral N-channel DMOS (NDMOS) devices, quasi vertical DMOS (QVDMOS) devices, FETs with isolated bodies from the substrate, etc., combined with Schottky diodes on a single semiconductor die. The Schottky diode can be integrated into a cell of the various DMOS devices by forming an N-type area in the P-body region of the DMOS device.

FIG. 1 shows a block diagram of a voltage converter 10 according to embodiments. The voltage converter 10 can include a metal oxide semiconductor field effect transistor (MOSFET) driver with dead time control 12 and a second MOSFET die 15 including one or more high side circuit devices 14 (e.g., FETs) and one or more low side circuit devices 16 (e.g., FET 30 and Schottky diode 25). Schottky diode 25 can be integrated with FET 30 (as will be discussed below). The Schottky diode 25 can be a junction barrier Schottky diode (JBS) (and will generally be referred to herein as a JBS). A JBS, as will be understood, can provide Schottky-like forward conduction and PN diode like reverse blocking of voltage. A JBS can include a PN junction and a Schottky junction diode in parallel. The low side devices 16 and the high side devices 14 can all be incorporated in a single semiconductor die (e.g., silicon, gallium arsenide, etc.). In embodiments, the high side devices 14 can be electrically connected to V_{IN} pinout and the low side devices 16 can be electrically connected to a power ground P_{GND}. Various other package pinouts and pin assignments also referred to as an output stage, such as those depicted in FIG. 1, can be included.

It will be understood that the embodiments below describe the formation of DMOS devices with integrated Schottky diodes. It will also be understood that while general manufacturing information is included, semiconductor manufacturing techniques are well known and can be tailored to the specific processes being used. It will also further be understood that while the Schottky diodes are shown integrated in a cell of the voltage converter, the Schottky diodes do not have to be integrated with every cell. For example, for 30V FETs a Schottky cell can be integrated in every fifth FET cell. In addition, a cell as used herein can include two DMOS with or without a Schottky diode integrated therein.

FIG. 2 shows a cross section of two half cells 206 of an integrated JIBS in DMOS. The cross section illustrates a first one 202 of the half cells 206 and a second one 204 of the half cells 206. As shown in FIG. 2, the first half cell 202 on the left is inverted as compared to the second half cell 204 on the right side. It will be appreciated that the terms “left” and “right” are relative to the illustration shown. It will be further appreciated that only one of the half cells is fully labeled with reference numbers, and that corresponding reference numbers are removed from the remaining side for purposes of clarity when viewing the figures. Each half cell 206 shown can include a P-type substrate 200 (that can have additional materials on the one or both sides 202, 204, not shown). The P-type substrate 200 can include, for example, silicon, GaAs, etc. A high voltage N-well layer (HVNW) 210 can be formed over the P-type substrate 200 (Concentration: 1e14-5e16 cm-3; depth 0.5-3 um from top surface).

The JBS 25 can include a Schottky metal 253 formed over the N2 region 260, where the N2 region 260 can be formed over the HVNW 210. The Schottky metal 253 can form the anode 280 of the JBS 25. The Schottky metal 253 can include, for example, Ti, Co, Pt, etc. These metals are in intimate contact with the silicon and form the metal silicides TiSi₂, CoSi₂, PtSi₂, etc. and combinations thereof with the appropriate temperature operation(s). It will be appreciated that Schottky metals other than those listed can be used. As shown in FIG. 2, the JBS 25 can be integrated in the lateral NDMOS 30 by inserting the N2 region 260 between adjacent lateral portions of the P2 well 220. The N2 region 260 can be approximately the same depth as the P2 well 220.

The lateral NDMOS 30 can include the P-type substrate 200 and the HVNW layer 210. A P2 well 220, a P1 well 215, and an N1 well 225 can be formed into the HVNW layer 210. These wells can have approximately the same depth from the surface of substrate 200. A shallow P+ well 250 can be formed in the P2 well 220. The P+ well 250 can include a depth of about ≦0.25 μm and a concentration of about >1×10¹⁹/cm³. A shallow N+ well 245 can be formed in the P1 well 215. The N+ well 245 can include a depth of about ≦0.25 μm and a concentration of about >1×10¹⁹/cm³). An N1 well 225 can be formed adjacent to the P1 well 215. In the N1 well 225, an N-type double diffused drain (NDDD) 230 can be formed and in the NDDD 230, an N+ well 235 can be formed.

The Schottky metal 253 can act as a source electrode 255 over the N+ well 245 and as a body contact 285 over the P+ well 250/P2 well 220. As a drain electrode 265, the same conductor material can be used for the source 255 and anode 280 and body 285. The drain electrode 265 can also act as the cathode terminal for the JBS 25. Over a portion of the N+ well 245, the P1 well 215 and the N1 well 225, e.g., a polysilicon gate 240 can be formed. The polysilicon gate can have a thickness of about 0.1 to about 1.0 μm. It will be appreciated that the simplification of the figures is such that the N+ is not necessarily under the polysilicon, and instead there can be an NLDD region under the polysilicon.

The N1 well 225 and the N2 region 260 can have a peak concentration of between about 1E15 and about 1E18 with a peak at a surface of the device (e.g. at a depth of about 0.0 μm) to about 1.0 μm. The N1 well 225, the N2 region 260, and the HVNW 210 layer can have the same or different doping concentrations depending on process requirements. Similarly, the P1 well 215 and the P2 well 220 can have a peak concentration between about 1E15 and about 1E18 with a peak at a depth of about 0.0 μm to about 1.0 μm. Similar to the N1 well 225, the HVNW 210, and the N2 region 260, P1 well 215 and P2 well 220 can have the same or different doping concentrations.

As shown in FIG. 2, the flow of carriers can follow one of two arrows 270 and 275 when a negative voltage is applied on drain or cathode 265 in reference to source and anode 280. Arrow 270 corresponds to the flow of the JBS 25 and arrow 275 corresponds to the flow through the drain/body PN diode in the lateral NDMOS 30. The flow of arrow 270 can be from the anode 280 (through Schottky metal 253) through N2 well 260, through HVNW layer 210, to N1 well 225, through NDDD shallow well 230, and through N+ well 235, ending at drain electrode 265. Note that along this path all the regions are N-type or same polarity. In contrast, the flow of arrow 275 can be from the body electrode 285, through P+ 250, through P2 well 220 through P1 well 215 and N1 well 225, to NDDD shallow well 230 to N+ well 235, and ending at drain electrode 265. The current flow in the direction of arrow 275 is due to a forward biased PN diode. With the disclosed embodiments, current in the path of 275 is minimized so that current in the path of 270 dominates. This is accomplished by using a JBS diode (formed between 253 and 260) in current path 270 and a PN junction diode (formed between 215 and 225 for example) for path 275. The forward turn-on voltage of the JBS diode is chosen to be less than the PN junction and the forward turn-on voltage of the Schottky diode is determined by the choice of metal. For example, Ti forms a Schottky diode on silicon with forward turn on voltage between 0.2-0.3 V as opposed to 0.5-0.7 V for PN junction). Because of this fact, combined with the observation the JBS and PN diodes are in parallel, the JBS diode turns on first and most of the current follows 270 rather than 275. The JBS diode switches from “on” to “off” much faster than a PN junction, so if we can clamp the voltage across the PN junction so that it does not turn on, then the transistor is faster and more efficient.

As shown in FIG. 2, the gate 240 of lateral NDMOS device 30 can be coplanar with the anode 280 of the JBS 25. Also as illustrated, N2 260, P2 220, P1 215, and N1 225 are approximately equal in depth and form parallel well structures between the surface of the device and the HVNW layer 210.

The various widths of the wells (e.g., P1, P2, N1, N2, etc.) can be adjusted to meet various processing and voltage requirements. For example, the width of the N2 region 260 can be adjusted to provide the desired voltage on (V_{ON}) and breakdown voltage (V_{BV}) characteristics. As discussed above, the JBS 25 can be integrated into every lateral NDMOS cell, but it does not have to be. If not integrated in a lateral NDMOS cell, then P2 220 can be a single continuous well as are N1 225, NDDD 230, and N+ 235.

FIG. 3 shows another embodiment according to present teachings. FIG. 3 shows a cross section of two half cells 306 of an integrated JBS with quasi vertical diffusion metal oxide semiconductor (QVDMOS) devices. The cross section illustrates a first one 302 of the half cells 306 and a second one 304 of the half cells 306. As shown in FIG. 3, the first half cell 302 on the left is inverted as compared to the second half cell 304 on the right. It will be appreciated that the terms “left” and “right” are relative to the illustration shown. It will be further appreciated that only one of the half cells is fully labeled with references numbers, and that corresponding reference numbers are removed from the remaining side for purposes of clarity when viewing the figure. Each half cell 306 shown can include a P-type substrate 300 (that can have additional materials on the both sides 302, 304, not shown). The P-type substrate 300 can include, for example, silicon, GaAs, etc. Over the P-type substrate 300 an N buried layer (NBL) 305 can be formed and over the NBL 305, a high voltage N-well layer (HVNW) 310 can be formed. The NBL 305 can have a concentration of about ≧1×10¹⁸/cm³ and the HVNW layer 310 can have a concentration of about <1×10¹⁷/cm³, with a depth of 1 to 20 μm as required to link with the NBL 305.

As shown in FIG. 3, the JBS 25 can include a Schottky metal 355 that can be formed over the N2 region 365, where the N2 region 365 can be formed in the HVNW 310. The Schottky metal 355 can form the anode 380 of the JBS 25. The Schottky metal 355 can include, for example, Ti, Co, Pt, etc. These metals are in intimate contact with the silicon and form the metal silicides TiSi₂, CoSi₂, PtSi₂, etc. and combinations thereof with the appropriate temperature operation(s). It will be appreciated that Schottky metals other than those listed can be used. As shown in FIG. 3, the JBS 25 can be integrated in the QVDMOS 30 by inserting the N2 region 365 between portions of the P2 well 320. The N2 region 365 can be approximately the same depth as the P2 well 320.

The QVDMOS 30 can include the P-type substrate 300, the NBL 305, and the HVNW layer 310. Into the HVNW layer 310, a P2 well 320, a P1 well 315, and an N1 well 325 can be formed. These wells can have approximately the same depth from the surface of the circuit side 302 of semiconductor substrate 300. In the P2 well 320 a P+ well 350 can be formed and in the P1 well 315 an N+ well 345 can be formed. Adjacent to the P1 well 315, an N1 well 325 can be formed. Adjacent to the N1 well 325, another P1 well 317 can be formed. In the P1 well 317, an additional N+ well 335 and a P+ well 340 can be formed. Another source electrode 353 and a body electrode 385 can be formed over N+ well 335 and P+ well 340. The electrode material 338 can be the same as the Schottky metal 355.

Adjacent to the P1 well 317 and the P+ well 340, a shallow trench isolation (STI) region can be formed. The isolation can alternatively be various oxide isolation techniques, for example, local oxidation of silicon (LOCOS), poly buffered LOCOS, etc. The STI region can also be adjacent to N+ well 370, i.e., between the P1 well 317/the P+well 340 and the N+ well 370. Over the N+ well 370 a drain electrode 375 can be formed. In alternative embodiments (not shown) additional N-type diffusions regions can be formed under the drain electrode 375.

The Schottky metal 355 can act as a source electrode 353 over the N+ well 345 and as a body 385 over the P+ well 350/P2 well 320. As a drain electrode 375, the same conductor material can be used to form the source 353 and anode 380. The drain electrode 375 can act as the cathode terminal for the JBS 25. Over a portion of the P1 well 315, the N1 well 325, and P1 315, e.g., a polysilicon gate 360 can be formed. The polysilicon gate can have a thickness of about 0.1 to about 1.0 μm. It will be appreciated that the simplification of the figures is such that the N+ is not necessarily under the polysilicon, and instead there can be an NLDD region under the polysilicon. Another source electrode 353 can be formed over the N+ well 335, and another body electrode can be formed over the P+ well 340.

The N1 well 325, the HVNW 310, and the N2 region 365 can have a peak concentration of between about 1E15 and about 1E18 cm-3 with a peak at a surface of the device (e.g. at a depth of about 0.0 μm) to about 1.0 μm. The N1 well 325, the N2 region 365, and the HVNW 310 layer can have the same or different doping concentrations depending on process requirements. Similarly, the P1 well 315, P1 well 317 and the P2 well 320 can have a peak concentration between about 1E15 and about 1E18 cm-3 with a peak at a depth of about 0.0 μm to about 1.0 μm. Similar to the N1 well 325, the HVNW 310, and the N2 region 365, the P1 well 315/317 and P2 well 320 can have the same or different doping concentrations. It will be appreciated that P1 can be the same as P2, such that P1 is large enough to span P1 and P2.

As shown in FIG. 3, the flow of majority carriers can follow the three (or more) arrows 392, 394, and 396. It will be appreciated, that by symmetry, half of the 392 arrow will go to the far left cathode terminal which is not numbered. Arrow 392 can correspond to the flow of the JBS 25 and arrows 394 and 396 can correspond to the flow of the drain/body PN diode in QVDMOS 30. The flow of arrow 392 can be from the anode 380, (through Schottky metal 355) through the N2 region 365, through the HVNW layer 310 and NBL 305, to N+ well 370 ending at drain electrode 375. In contrast, the flow of arrow 394 can be from the body electrode 385, to the P+ well 350, to P2 well 320, and P1 well 315, to HVNW 310 to N+ well 370 ending at drain electrode 375. Similarly, the flow of arrow 396 can be from body electrode 338 to P+ 340, to P1 well 317 to HVNW 310 to N+ well 370 ending at drain electrode 375. As can be seen, the QVDMOS 30 has an approximate vertical flow as compared to the lateral NDMOS shown in FIG. 2.

As shown in FIG. 3 the gate 360 of the QVDMOS device 30 can be coplanar with the anode 380 of the JBS 25. Also as illustrated, N2 region 365, P2 well 320, P1 wells 315, 317, and N1 well 325 can be approximately equal in depth and form parallel well structures between the surface of the device, the HVNW layer 310, and the NBL 305.

The various widths of the wells (e.g., P1, P2, N1, N2, etc.) can be adjusted to meet various processing and voltage requirements. For example, the width of the N2 region 365 can be adjusted to provide desired voltage on (V_{ON}) and breakdown voltage (V_{BV}) characteristics. As discussed above, the JBS 25 can be integrated into every QVDMOS 30 cell, but it does not have to be. If not integrated in a QVDMOS cell, then P2 320 can be a single continuous well. N+ 370 can be further isolated by another STI. For example, with another STI on the right side of 370, then another source/body/gate similar to 385/353/360 but mirrored through the center of 375 can be provided.

FIG. 4 shows an example simulation of the doping concentrations according to present teachings for a JBS 25 integrated with a lateral NDMOS 30. As shown, the lateral NDMOS 30 has a drain electrode 265, a gate 240, and a source electrode 255. Also shown are the lateral NDMOS 30 body 285 and the anode 280 of the JBS 25. As shown, between the gate 240 and the body 285 is a predominately P-type 410 area with a small shallow N-type region 415 between the gate 240 and the source 255. In contrast, the area surrounding the predominately P-type area is a large area of varying N-type concentrations 420.

FIG. 5 shows a current-voltage (drain) graph comparing the total current in the body 520 of e.g., the lateral NDMOS of FIG. 2, to the total current of the anode 510 of an integrated Schottky diode. As shown, the Schottky current 510 is significantly higher than the body current 520 in the third quadrant. In other words, when the NDMOS drain bias is negative with respect to the body and anode, then the JBS diode conducts most of the current because it turns on at a lower voltage than the drain/body PN junction.

In FIG. 6, a voltage converter device in accordance with the present teachings can be attached along with other semiconductor devices such as one or more microprocessors to a printed circuit board, for example to a computer motherboard, for use as part of an electronic system such as a personal computer, a minicomputer, a mainframe, or another electronic system. A particular embodiment of an electronic system 630 is depicted in the block diagram of FIG. 6. The electronic system 630 can include a voltage converter device 632 such as one according to the present teachings. The voltage converter device 632 can include a first die (e.g. power die) 634 having a low side 636, including, for example, a LDMOS or a lateral NDMOS FET including an integrated Schottky diode, and a high side 638, including for example a LDMOS FET 638 on the same semiconductor substrate, and a second die (controller die) 640 which can include a controller/voltage regulator. The electronic system can further include a processor 642 which may be one or more of a microprocessor, microcontroller, embedded processor, digital signal processor, or a combination of two or more of the foregoing. Electronic system 630 can further include one or more memory devices such as static random access memory, dynamic random access memory, read only memory, flash memory, or a combination of two or more of the foregoing. Other components 646 can also be included, which will vary with the type of electronic device. The voltage converter device 632, processor 642, memory 644, and other components 646 can be powered by a power source (power supply) 648, which may be a converted AC power source or a DC power source such as a DC power supply or battery. The processor 642 can be electrically coupled to, and communicate with, the voltage converter device 632 through at least one first data bus 650, the memory through at least one second data bus 654, and the other components 646 through at least one third data bus 652. Thus electronic system 630 may be a device related to telecommunications, the automobile industry, semiconductor test and manufacturing equipment, consumer electronics, or virtually any piece of consumer or industrial electronic equipment.

It will be evident to one of ordinary skill in the art that the processes and resulting structures previously described can be modified to form various semiconductor device features having different patterns, widths, and/or materials using a single mask step. Exemplary methods and resulting structures are described below.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values, in this case, the example value of range stated as “less that 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the present disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. As used herein, the term “one or more of” with respect to a listing of items such as, for example, A and B or A and/or B, means A alone, B alone, or A and B. The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the methods and structures disclosed herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate. It is intended that the specification and examples be considered as exemplary only, with a true scope and spirit of the invention being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A semiconductor device voltage converter, comprising:
a semiconductor die having a circuit side and a non-circuit side; and
an output stage on the circuit side of the semiconductor die, the output stage comprising:
a lateral N-type diffusion metal oxide semiconductor (NDMOS) device having a body isolated from the non-circuit side of the semiconductor die; and
a Schottky diode integrated into the semiconductor die;
wherein the Schottky diode is integrated into a cell of the NDMOS device by forming an n-type area in a P-body region of the NDMOS device.

2. The semiconductor device voltage converter of claim 1, wherein in a cross section perpendicular to the circuit side of the semiconductor die, a gate of the NDMOS device and an anode of the Schottky diode are coplanar in a plane which is parallel with the circuit side of the semiconductor die.

3. The semiconductor device voltage converter of claim 1, wherein the Schottky diode comprises:
an anode formed by a source metal of the NDMOS; and
a cathode terminal formed by a drain metal of the NDMOS.

4. The semiconductor device voltage converter of claim 3, wherein the Schottky diode comprises a Schottky metal.

5. The semiconductor device voltage converter of claim 4, wherein the Schottky metal comprises at least one of Ti, Co, Pt, and wherein contact of the metals with silicon form metal silicides comprising TiSi₂, CoSi₂, PtSi₂, and combinations thereof.

6. The semiconductor device voltage converter of claim 1, further comprising:
the output of the output stage comprises a drain of the NDMOS device and a cathode terminal of the Schottky diode.

7. The semiconductor device voltage converter of claim 1, further comprising:
a second lateral NDMOS device wired in parallel with the first lateral NDMOS to configure a single transistor, and wherein the Schottky diode is integrated into a cell of the second NDMOS device by forming an n-type area in a P-body region of the second NDMOS device.

8. The semiconductor device voltage converter of claim 1, wherein the Schottky diode comprises a junction barrier N-type Schottky region.

9. The semiconductor device voltage converter of claim 8, wherein the junction barrier Schottky region has a width selected to optimize on voltage (Vₒₙ) characteristics and breakdown voltage characteristics of the voltage converter.

10. The semiconductor device voltage converter of claim 9, wherein the junction barrier Schottky region has about an equal dopant concentration as an N-type diffusion region of the NDMOS device.

11. The semiconductor device voltage converter of claim 1, wherein a current path through the Schottky diode dominates over a current path through a drain/body PN junction.

12. The semiconductor device voltage converter of claim 11, wherein the Schottky diode begins conducting first, thereby limiting the forward bias voltage across the drain/body PN junction, such that less minority carries are generated at the PN junction, thereby obtaining a faster switching speed.

13. A semiconductor device voltage converter, comprising:
a semiconductor die having a circuit side and a non-circuit side; and
an output stage on the circuit side of the semiconductor die, the output stage comprising:
a quasi vertical N-type diffusion metal oxide semiconductor (QVDMOS) device;
a Schottky diode integrated into the semiconductor die; and
an output;
wherein the Schottky diode is integrated into a cell of the QVDMOS device by forming an n-type area in a P-body region of the QVDMOS device.

14. The semiconductor device voltage converter of claim 13, wherein in a cross section perpendicular to the circuit side of the semiconductor die, a gate of the QVDMOS device and an anode of the Schottky diode are coplanar in a plane which is parallel with the circuit side of the semiconductor die.

15. The semiconductor device voltage converter of claim 14, wherein the Schottky diode comprises a Schottky metal.

16. The semiconductor device voltage converter of claim 15, wherein the Schottky metal comprises at least one of at least one of Ti, Co, Pt, and wherein contact of the metals with silicon form metal silicides comprising TiSi₂, CoSi₂, PtSi₂, and combinations thereof.

17. The semiconductor device voltage converter of claim 13, further comprising:
a second QVDMOS device wired in parallel with the first QVDMOS device to configure a single transistor, and wherein the Schottky diode is integrated into a cell of the second QVDMOS device by forming an n-type area in a P-body region of the second QVDMOS device.

18. The semiconductor device voltage converter of claim 13, wherein a drain of the QVDMOS device is isolated from a source, a body, and a gate of the QVDMOS device.

19. The semiconductor device voltage converter of claim 13, wherein the Schottky diode comprises a junction barrier N-type Schottky region.

20. The semiconductor device voltage converter of claim 17, wherein the junction barrier Schottky region has a width selected to optimize on voltage (Vₒₙ) characteristics and breakdown voltage characteristics of the voltage converter.

21. The semiconductor device voltage converter of claim 20, wherein the junction barrier Schottky region has about an equal dopant concentration as an N-type diffusion region of the NDMOS device.

22. The semiconductor device voltage converter of claim 13, wherein a current path through the Schottky diode dominates over a current path through a drain/body PN junction.

23. The semiconductor device voltage converter of claim 22, wherein the Schottky diode begins conducting first, thereby limiting the forward bias voltage across the drain/body PN junction, such that less minority carries are generated at the PN junction, thereby obtaining a faster switching speed.

24. A method for forming a semiconductor device voltage converter, comprising:
forming an output stage on a single semiconductor die with a method comprising:
forming a lateral N-type diffusion metal oxide semiconductor (NDMOS) device having a body isolated from a non-circuit side of the semiconductor die;
forming a Schottky diode integrated into the semiconductor die; and
forming an output of the output stage;
electrically connecting the output of the output stage to a non-circuit side of the semiconductor die,
wherein the Schottky diode is integrated into a cell of the NDMOS device by forming an n-type area in a P-body region of the NDMOS device.

25. A method for forming a semiconductor device voltage converter, comprising:
forming an output stage on a single semiconductor die with a method comprising:
forming a quasi vertical N-type diffusion metal oxide semiconductor (QVDMOS) device having a body isolated from a non-circuit side of the semiconductor die;
forming a Schottky diode integrated into the semiconductor die; and
forming an output of the output stage;
electrically connecting the output of the output stage to a non-circuit side of the semiconductor die,
wherein the Schottky diode is integrated into a cell of the QVDMOS device by forming an n-type area in a P-body region of the QVDMOS device.

26. An electronic system comprising:
a voltage converter device, comprising:
a semiconductor die comprising a circuit side and a non-circuit side;
a lateral N-type diffusion metal oxide semiconductor (NDMOS) device having a body isolated from a non-circuit side of the semiconductor die;
a Schottky diode integrated into the semiconductor die, wherein the Schottky diode is integrated into a cell of the NDMOS device by forming an n-type area in a P-body region of the NDMOS device; and
an output stage, wherein the output stage is electrically connected to the to the drain region of the low side NDMOS;
a processor electrically coupled to the voltage converter device through a first data bus;
memory electrically coupled to the processor through a second data bus; and
a power source which powers the voltage converter device, the processor, and the memory.

27. The electronic system of claim 26, wherein the Schottky diode is integrated into the NDMOS at a cell spacing selected from every cell, every other cell, and every 5^{th} cell.

28. An electronic system comprising:
a voltage converter device, comprising:
a semiconductor die comprising a circuit side and a non-circuit side;
a quasi vertical N-type diffusion metal oxide semiconductor (QVDMOS) device having a body isolated from a non-circuit side of the semiconductor die;
a Schottky diode integrated into the semiconductor die, wherein the Schottky diode is integrated into a cell of the QVDMOS device by forming an n-type area in a P-body region of the QVDMOS device; and
an output stage, wherein the output stage is electrically connected to the to the drain region of the low side QVDMOS;
a processor electrically coupled to the voltage converter device through a first data bus;
memory electrically coupled to the processor through a second data bus; and
a power source which powers the voltage converter device, the processor, and the memory.

29. The electronic system of claim 28, wherein the Schottky diode is integrated into the QVDMOS at a cell spacing selected from every cell, every other cell, and every 5^{th} cell.
